(19) United States
(12) Patent Application Publication
(10) Pub. No.: US 2026/0194602 A1
(43) Pub. Date: Jul. 9, 2026

(54) EARLY DETECTION OF METALLIZED FILM CAPACITOR FAILURE

(71) Applicant: INTERNATIONAL BUSINESS MACHINES CORPORATION, Armonk, NY (US)

(72) Inventors: Joseph Prisco, Rochester, MN (US); Brian Charles Tucker, Clinton Corners, NY (US); Marc Henri Coq, Hopewell Junction, NY (US); Enver Candan, Cornwall, NY (US)

(21) Appl. No.: 19/014,363

(22) Filed: Jan. 9, 2025

(51) Int. Cl. G01R 31/64; G08B 21/18

(52) U.S. Cl. CPC G01R 31/64; G08B 21/185

(57) ABSTRACT

Embodiments of present invention provide a method of preventing high-voltage system failure. The method includes placing a metallized film capacitor (MFC) in an active operation mode in a high-voltage system; detecting one or more partial discharge (PD) events in the MFC; counting the one or more PD events; and in response to a total number of the PD events reaching a pre-determined threshold, replacing the MFC in the high-voltage system before the MFC fails. A high-voltage system with a metallized film capacitor is also provided.

### BACKGROUND

The present application relates to method of preventing application failure caused by a metallized film capacitor. More particularly, it relates to monitoring and detecting partial discharge in a metallized film capacitor during active operation and related application system.

Metallized film capacitors belong to a capacitor technology and are often utilized in a variety of high-voltage systems. These applications include, for example, electromagnetic Interference suppression, harmonic distortion suppression, and localized pulse filtering in power supply switching networks. Metallized film capacitors are typically reliable, but even their occasional failure can have significant consequences such as smoke and fire, causing the application to fail to perform as intended.

When utilized in industrial/utility applications, metallized film capacitors, when failing to perform, can cause catastrophic consequences such as unplanned downtime and facility repair due to fire and/or smoke damage to high voltage switchgear. Thus, metallized film capacitors typically require annual testing to ensure that they are not nearing their end of life so as to prevent catastrophic failure. However, these test procedures are invasive and disruptive to the facility as personnel need to shut down, isolate, and often remove the equipment or capacitor from the board as well as enter dangerous spaces to perform such tasks. When utilized in smaller applications, such as IT equipment, failure of the metallized film capacitors typically results in unwanted radio frequency emissions as well as smoke and/or fire.

Moreover, if a metallized film capacitor fails outright, it is typically difficult, if not impossible, to perform failure analysis on the part of the failing capacitor, thus harming the ability to determine if the failure was application related.

### SUMMARY

Embodiments of present invention provide a method of preventing high-voltage system failure. The method includes placing a metallized film capacitor (MFC) in an active operation mode in a high-voltage system; detecting one or more partial discharge (PD) events in the MFC; counting the one or more PD events; and in response to a total number of the one or more PD events reaching a pre-determined threshold, replacing the MFC in the high-voltage system before the MFC fails.

According to one embodiment, the method further includes receiving an electric signal at the MFC; and detecting the one or more PD events by analyzing the electric signal.

In one embodiment, analyzing the electric signal includes causing the electric signal to pass through a high-pass filter thereby receiving a filtered signal having no low-frequency components of the electric signal; comparing the filtered signal with a spike reference; and counting as one PD event in response to the filtered signal being equal to or larger than the spike reference. In another embodiment, the high-pass filter has a 3-dB corner frequency of 10 megahertz (MHz) or higher.

In one embodiment, the electric signal is a fraction of an electric current passing through one terminal of the MFC, the electric current flowing between the one terminal of the MFC and a common-mode filter in the high-voltage system.

In another embodiment, the electric signal is a voltage signal measured at two terminals of the MFC and is received through a pair of tapping capacitors.

In yet another embodiment, the electric signal is a voltage signal measured at two opposing sides of the MFC and is received through a pair of metal plates placed at the two opposing sides of the MFC.

According to another embodiment, the method further includes causing the electric signal to pass through a low-pass filter thereby receiving a current signal having no PD related components of the electric signal; measuring a voltage across two terminals of the MFC; estimating a capacitance of the MFC based on the current signal and the measured voltage; and replacing the MFC in response to the capacitance of the MFC being estimated to be below a pre-determined value.

Embodiments of present invention further provide a high-voltage system. The system includes an AC main circuit; a metallized film capacitor (MFC) connected to the AC main circuit via a common-mode filter; and a test circuit electrically coupled to the MFC, where the testing circuit is adapted to receive an electric signal from the MFC; detect and count partial discharge (PD) events happening in the MFC; and raise an alarm in response to a total number of the PD events reaching a pre-determined threshold.

In one embodiment, the test circuit includes a high-pass filter adapted to receive a filtered signal, from the electric signal, with no low-frequency components of the electric signal; a comparator to compare the filtered signal with a spike reference to detect the PD events; and an event counter to count the PD events. In another embodiment, the high-pass filter has a 3-dB corner frequency of 10 megahertz (MHz) or higher.

In one embodiment, the electric signal is a fraction of an electric current and the test circuit includes a current sensor connected to one terminal of the MFC to receive the fraction of the electric current.

In another embodiment, the electric signal is a voltage signal, and the test circuit includes two tapping capacitors connected respectively to two terminals of the MFC to receive the voltage signal.

In yet another embodiment, the electric signal is a voltage signal, and the test circuit includes two metal plates placed at two opposing sides of the MFC electrically coupled to the MFC to receive the voltage signal.

According to one embodiment, the test circuit further includes a first low-pass circuit adapted to receive a current signal having no PD related components of the electric signal; a second low-pass circuit adapted to measure a voltage across two terminals of the MFC; and an integrator adapted to estimate a capacitance of the MFC based on the current signal and the measured voltage.

Embodiments of present invention additionally provide a method of preventing high-voltage system failure. The method includes placing a metallized film capacitor (MFC) in an active operation mode in a high-voltage system; receiving an electric signal associated with the MFC; detecting one or more partial discharge (PD) events in the MFC by analyzing the electric signal; counting the one or more PD events; and in response to a total number of the one or more PD events reaching a pre-determined threshold; recommending the MFC in the high-voltage system being replaced.

In one embodiment, detecting the one or more PD events includes causing the electric signal to pass through a high-pass filter thereby receiving a filtered signal having no low-frequency components of the electric signal; comparing the filtered signal with a spike reference; and counting as one PD event in response to the filtered signal carrying a same characteristic as a characteristic provided by the spike reference.

In another embodiment, the characteristic provided by the spike reference is selected from a group consisting of frequency components; shape of electric current, shape of voltage signal; and amplitude of electric signal.

In one embodiment, the high-pass filter has a 3-dB corner frequency of 10 megahertz (MHz) or higher.

According to one embodiment, the method further includes, in response to a total number of the one or more PD events reaching the pre-determined threshold, recommending replacing the MFC by raising an alarm, making a voice announcement, or sending out a text message.

### BRIEF DESCRIPTION OF THE DRAWINGS

The present invention will be understood and appreciated more fully from the following detailed description of embodiments of present invention, taken in conjunction with accompanying drawings of which:

FIG. 1 is a simplified block diagram of a high-voltage system having a metallized film capacitor according to one embodiment of present invention;

FIG. 2 is a simplified block diagram of a high-voltage system having a metallized film capacitor according to another embodiment of present invention;

FIG. 3 is a simplified block diagram of a high-voltage system having a metallized film capacitor according to yet another embodiment of present invention;

FIG. 4 is a simplified block diagram of a high-voltage system having a metallized film capacitor according to a further embodiment of present invention; and

FIG. 5 is a demonstrative illustration of a flow-chart of a method of preventing failure of a high-voltage system according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

It is to be understood that in the below description, the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers, elements, or structures are intended to be broadly construed and should not be interpreted as precluding the presence of one or more intervening layers, elements, or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

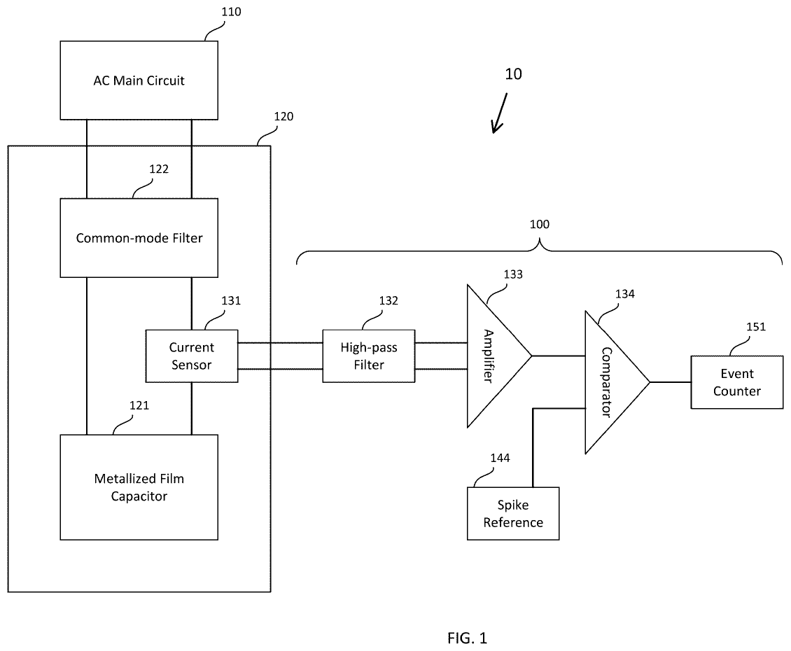

FIG. 1 is a simplified block diagram of a high-voltage system having a metallized film capacitor according to one embodiment of present invention. More particularly, the embodiment provides a high-voltage system 10 that includes an AC main circuit 110 and a capacitor unit 120 that is connected to, or electrically coupled with, the AC main circuit 110. The capacitor unit 120 is connected to the AC main circuit 110 to provide electromagnetic interference suppression, harmonic distortion suppression, and/or localized pulse filtering in the case of power switching networks. The capacitor unit 120 may include, for example, a metallized film capacitor (MFC) 121 and a common-mode filter 122. The MFC 121 is connected to the AC main circuit 110 via the common-mode filter 122 at a first and a second terminals.

According to one embodiment, the capacitor unit 120 may further include an electrical element that is electrically coupled to, related with, or associated with the MFC 121 so as to detect, sense, share, or receive an electric signal that is associated with the MFC 121. For example, the electric signal may be a fraction or a portion of an electric current that flows or goes through the MFC 121. The amount of the fraction or portion may be known or pre-fixed such that it may be scaled to represent the actual electric current going through the MFC 121. This electrical signal may have exact same characteristics, such as waveform shape or form, or frequency components, as the electric current going through the MFC 121. In the high-voltage system 10, this electrical element may be a current sensor 131, which may be tapped onto one terminal of the MFC 121 and serially connected between the MFC 121 and the common-mode filter 122. The electric signal going through the MFC 121 may be detected by the current sensor 131.

According to one embodiment, the high-voltage system 10 may further include a signal processing circuit 100 that is adapted to process the fraction of the electric signal going through the MFC 121, that is received by the electrical element such as the current sensor 131 in the capacitor unit 120. The signal processing circuit 100 may include, for example, a high-pass filter 132 connected to an output of the current sensor 131, an operational amplifier 133 connected to an output of the high-pass filter 132, and a signal comparator 134. The signal comparator 134 has two input ports with a first input port being connected to an output of the operational amplifier 133 and a second input port being connected to a spike reference device 144. An output of the signal comparator 134 is then connected to an event counter 151.

During normal operation, the capacitor unit 120 is connected to the AC main circuit 110 thereby placing the MFC 121 into an active operation mode. The MFC 121 may provide its normal functionality such as suppressing electromagnetic interference, distortion, and/or noises in the electric current that goes, via the MFC 121, into the AC main circuit 110. However, due to aging and other imperfection, the MFC 121 may sometimes and over time experience undesirable events internally such as partial discharge (PD) events. These PD events may cause, for example, the metallized layer or film inside the MFC 121 to breakdown, resulting in damages to the internal plastic dielectric material, and ultimately cause the MFC to fail.

According to embodiments of present invention, the signal processing circuit 100 of the high-voltage system 10 provides detecting, monitoring, evaluating, and/or recommending functions that help prevent and/or reduce unexpected failures of the high-voltage system 10 proactively. For example, by applying the signal processing circuit 100, embodiment of present invention provides a method of preventing unexpected failure of the high-voltage system 10 by placing the MFC 121 in the system 10 into an active operation mode; constantly monitoring the high-voltage system 10 to detect any PD events that may happen inside the MFC 121; counting a total number or accumulated sum of the PD events; and in response to the total number of PD events reaching a pre-determined threshold recommending proactively replacing the MFC 121 in the high-voltage system 10, before the MFC 121 actually fails, so as to prevent unexpected failure of the high-voltage system 10.

For example, from the current sensor 131, the high-pass filter 132 may receive a fraction or a portion of the electric current that goes through the MFC 121. When a PD event happens inside the MFC 121 thereby resulting in a spike signal in the electric current going through the MFC 121, the high-pass filter 132 may be able to substantially filter out low-frequency components of the electric current and pass only high-frequency components that are related to the spike signal caused by the PD onto the operational amplifier 133. For example, the high-pass filter 132 may have a 3-dB corner frequency of 10 Megahertz (MHz) or higher such that frequency components that are at or lower than 10 MHz may be filtered out, causing only frequency components that are higher than 10 MHz to pass through the high-pass filter 132 thereby receiving or producing a filtered signal with substantially no low-frequency components of the electric signal. The operational amplifier 133 operates to enhance sensitivity of the signal processing circuit 100 by amplifying the filtered signal from the high-pass filter 132 and pass the amplified filtered signal onto the signal comparator 134. The signal comparator 134 compares the filtered signal from the operational amplifier 133 with a spike reference from the spike reference device 144. After determining that the filtered signal carries substantially a same characteristic as a PD event, such as a characteristic of the spike reference provided by the spike reference device 144 and selected from a group consisting of frequency components; shape of electric current, shape of voltage signal; and amplitude of electric signal, the event counter 151 counts the detection of this filtered signal as one PD event. The characteristic of a PD event may include, for example, frequency components, shape and form of the filtered signal, whether it is electric current or voltage signal, and magnitude or amplitude of the filtered signal. In one embodiment, the event counter 151 counts the detection of this filtered signal as one PD event in response to the filtered signal being equal to or larger than the spike reference.

The event counter 151 counts a total number or accumulated sum of the PD events and in response to a pre-determined number, threshold level, or value of the PD events having been reached, the MFC 121 may be flagged as “bad” that needs to be handled preemptively. For example, the event counter 151 may provide a recommendation, such as through setting off or raising an alarm, making a voice announcement, sending out a text message, etc., that recommends that the MFC 121 in the high-voltage system 10 be replaced, preemptively or proactively, to prevent a future unexpected failure of the high-voltage system 10 which could be caused by the failure of the MFC 121. Otherwise, such unexpected failures may result in system downtime and/or damage to the system.

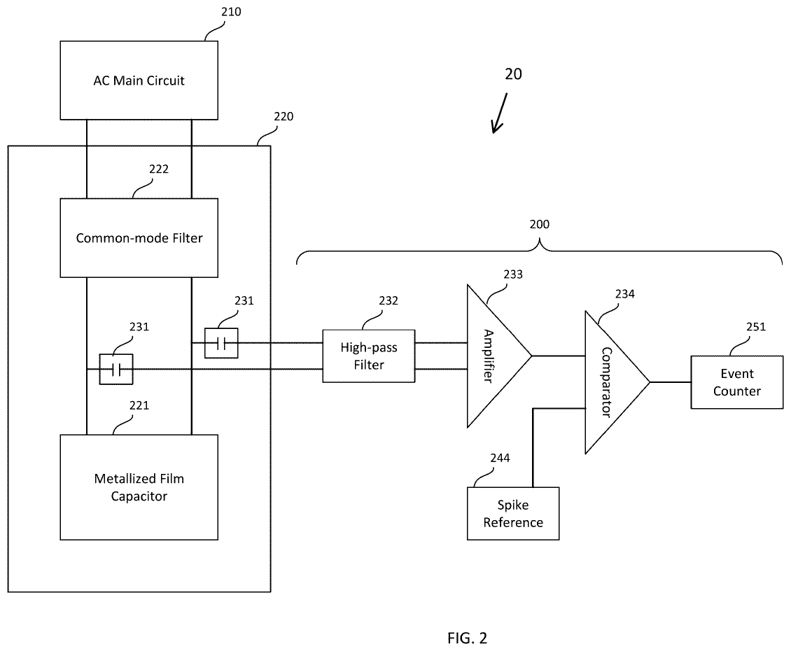

FIG. 2 is a simplified block diagram of a high-voltage system having a metallized film capacitor according to another embodiment of present invention. More particularly, the embodiment provides a high-voltage system 20 that includes an AC main circuit 210 and a capacitor unit 220 that is connected to, or electrically coupled with, the AC main circuit 210. The capacitor unit 220 is connected to the AC main circuit 210 to provide electromagnetic interference suppression, harmonic distortion suppression, and/or localized pulse filtering in power switching networks. The capacitor unit 220 may include, for example, a MFC 221 that is connected to the AC main circuit 210 via a common-mode filter 222 at a first and a second terminals.

According to one embodiment, the capacitor unit 220 may further include an electrical element that is electrically coupled to, related with, or associated with the MFC 221 so as to detect, sense, share, or receive an electric signal that is associated with the MFC 221. For example, the electric signal may be a voltage signal across the MFC 221, and the voltage signal may be detected through a pair of tapping capacitors 231 tapped off the two terminals of the MFC 221. In other words, the pair of tapping capacitors 231 may be connected in parallel with the MFC 221 as well as the common-mode filter 222. The pair of tapping capacitors 231 may de-couple low-frequency or DC components of the electric signal from the MFC 221.

According to one embodiment, the high-voltage system 20 may further include a signal processing circuit 200 that is adapted to process the electric signal from the electrical element such as the pair of tapping capacitors 231 in the capacitor unit 220. Similar to the signal processing circuit 100, the signal processing circuit 200 may include a high-pass filter 232 connected to the tapping capacitors 231, an operational amplifier 233 connected to an output of the high-pass filter 232, and a signal comparator 234. The high-pass filter 232 may have a 3-dB corner frequency of 10 MHz or higher letting only frequency components that are higher than 10 MHz pass through. The signal comparator 234 has two input ports with a first input port being connected to an output of the operational amplifier 233 and a second input port being connected to a spike reference device 244. An output of the signal comparator 234 is then connected to an event counter 251.

During normal operation, the capacitor unit 220 is connected to the AC main circuit 210 thereby placing the MFC 221 into an active operation mode. The signal processing circuit 200 of the high-voltage system 20 provides detecting, monitoring, evaluating, and recommending functions by, for example, constantly monitoring the high-voltage system 20 to detect any PD events that may happen inside the MFC 221; counting a total number or accumulated sum of the PD events; and, in response to the total number of PD events reaching a pre-determined threshold and before the MFC 221 actually fails, recommending proactively replacing the MFC 221 in the high-voltage system 20 so as to prevent unexpected failure of the high-voltage system 20.

For example, the high-pass filter 232 may receive a voltage signal across the two terminals of the MFC 221 via the pair of tapping capacitors 231. When a PD event happens inside the MFC 221 thereby resulting in a spike signal in voltage signal across the MFC 221, the high-pass filter 232 may be able to substantially filter out low-frequency components of the voltage signal and pass only high-frequency components that are related to the spike signal caused by the PD event, as a filtered signal, onto the operational amplifier 233. The operational amplifier 233 amplifies the filtered signal from the high-pass filter 232 and pass the amplified filtered signal onto the signal comparator 234 for further processing. The signal comparator 234 compares the filtered signal from the operational amplifier 233 with a spike reference from the spike reference device 244. The spike reference from the spike reference device 244 may carry a characteristic that is selected from a group consisting of frequency components; shape of electric current, shape of voltage signal; and amplitude of electric signal. After determining that the filtered signal carries a substantially same characteristic as that of a PD event, such as frequency components; shape and form in electric current or voltage signal; and magnitude or amplitude in the filtered signal, or after determining that the filtered signal is equal to or larger than the spike reference, the event counter 251 counts the detection of this filtered signal as a PD event. The event counter 251 counts a total number or accumulated sum of the PD events and in response to a pre-determined number of PD events having been reached, the MFC 221 may be flagged as “bad” and may need to be handled preemptively. For example, the event counter 251 may recommend having the MFC 221 replaced to prevent a future unexpected failure of the high-voltage system 20 caused by the failure of the MFC 221. Such recommendation may be made through setting off or raising an alarm, making an announcement, and/or sending out a text message.

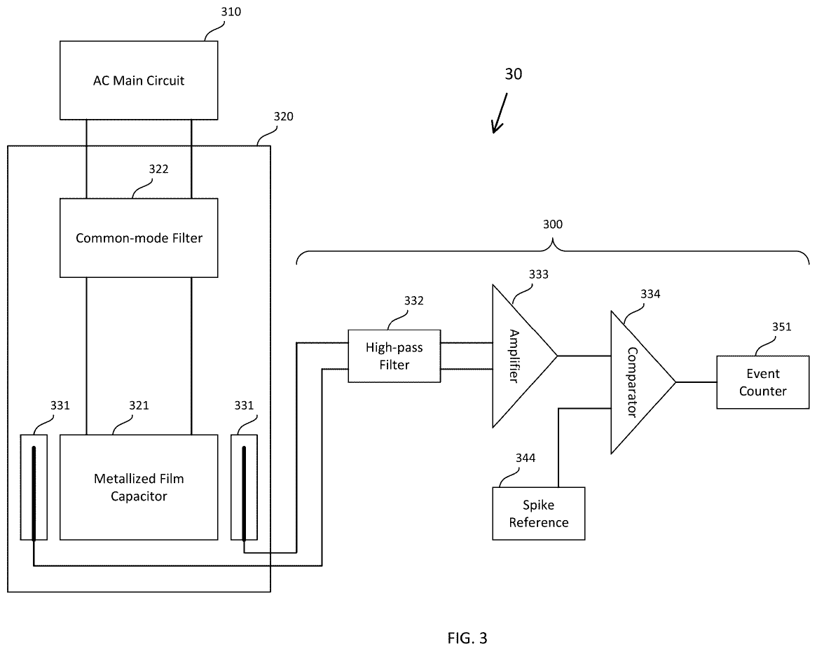

FIG. 3 is a simplified block diagram of a high-voltage system with a metallized film capacitor according to yet another embodiment of present invention. More particularly, the embodiment provides a high-voltage system 30 that includes an AC main circuit 310 and a capacitor unit 320 that is connected to, or electrically coupled with, the AC main circuit 310. The capacitor unit 320 is connected to the AC main circuit 310 to provide electromagnetic interference suppression, harmonic distortion suppression, and/or localized pulse filtering in power switching networks. The capacitor unit 320 may include a MFC 321 that is connected to the AC main circuit 310 via a common-mode filter 322 at a first and a second terminals.

According to one embodiment, the capacitor unit 320 may further include an electrical element that is electrically coupled to, related with, or associated with the MFC 321 so as to detect, sense, share, or receive an electric signal that is associated with the MFC 321. For example, the electric signal may be a voltage signal across the MFC 321, and the voltage signal, in particular a change in value of the voltage signal over time, may be detected by a pair of metal plates 331. The pair of metal plates may be placed at two opposing sides of the MFC 321 and encased in an insulator. The change in value of the voltage signal over time may be detected by the pair of metal plates 331 through electrostatic coupling and information thereof may be passed onto a signal processing circuit 300 for further processing.

According to one embodiment, the high-voltage system 30 may further include the signal processing circuit 300 that is adapted to process the electric signal from the electrical element such as the pair of metal plates 331 in the capacitor unit 320. Similar to the signal processing circuit 100, the signal processing circuit 300 may include a high-pass filter 332 connected to the pair of metal plates 331, an operational amplifier 333 connected to an output of the high-pass filter 332, and a signal comparator 334. The high-pass filter 332 may have a 3-dB corner frequency of 10 MHz or higher letting only frequency components that are higher than 10 MHz to pass through. The signal comparator 334 has two input ports with a first input port being connected to an output of the operational amplifier 333 and a second input port being connected to a spike reference device 344. An output of the signal comparator 334 is then connected to an event counter 351.

During normal operation, the capacitor unit 320 is connected to the AC main circuit 310 thereby placing the MFC 321 into an active operation mode. The signal processing circuit 300 of the high-voltage system 30 provides detecting, monitoring, evaluating, and recommending functions by, for example, constantly monitoring the high-voltage system 30 to detect any PD events that may happen inside the MFC 321; counting a total number or accumulated sum of the PD events; and, in response to the total number of the PD events reaching a pre-determined threshold and before the MFC 321 actually fails, recommending to proactively replace the MFC 321 in the high-voltage system 30 so as to prevent unexpected failure of the high-voltage system 30.

For example, the high-pass filter 332 may receive an electric signal related to voltage variation over time at the MFC 321 via the pair of metal plates 331. When a PD event happens inside the MFC 321 resulting in a spike signal in the voltage across the MFC 321, the high-pass filter 332 may be able to filter out low-frequency components of the voltage signal and pass only high-frequency components that are related to the spike caused by the PD event onto the operational amplifier 333 as a filtered signal. The operational amplifier 333 amplifies the filtered signal and pass that amplified filtered signal onto the signal comparator 334 for further processing. The signal comparator 334 compares the filtered signal from the operational amplifier 333 with a spike reference signal from the spike reference device 344. The spike reference from the spike reference device 344 may carry a characteristic that is selected from a group consisting of frequency components; shape of electric current, shape of voltage signal; and amplitude of electric signal. After determining that the spike signal carries a substantially same characteristic as that of a PD event such as frequency components, shape and/or form in voltage variation, or the magnitude or amplitude of the filtered signal is equal to or larger than a spike reference, the event counter 351 counts the detection of the filtered signal as a PD event. The event counter 351 counts a total number or accumulated sum of the PD events and in response to a pre-determined threshold of PD events having been reached, the MFC 321 may be flagged as “bad” that needs to be handled preemptively. For example, the event counter 351 may recommend having the MFC 321 being replaced to prevent a future unexpected failure of the high-voltage system 30 that may be caused by an unexpected failure of the MFC 321.

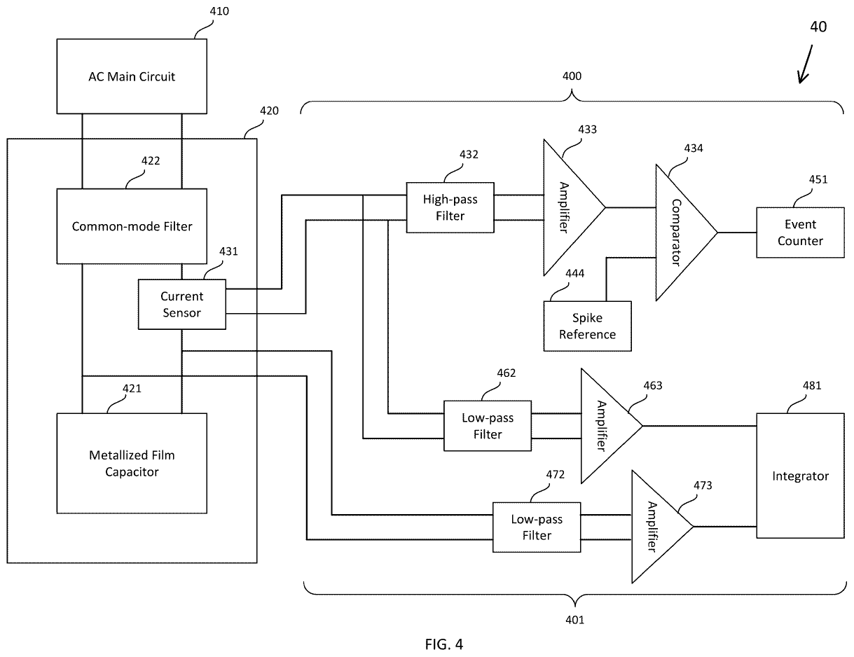

FIG. 4 is a simplified block diagram of a high-voltage system with a metallized film capacitor according to a further embodiment of present invention. More particularly, the embodiment provides a high-voltage system 40 that includes an AC main circuit 410 and a capacitor unit 420 that is connected to, or electrically coupled with, the AC main circuit 410. The capacitor unit 420 is connected to the AC main circuit 410 to provide electromagnetic interference suppression, harmonic distortion suppression, and/or localized pulse filtering in power switching networks. The capacitor unit 420 may include, for example, a MFC 421 that is connected to the AC main circuit 410 via a common-mode filter 422 at a first and a second terminals.

Like in the high-voltage system 10, the capacitor unit 420 in the high-voltage system 40 may include a current sensor 431, which is tapped onto one terminal of the MFC 421, and a signal processing circuit 400 that is adapted to process a fraction of an electric signal going through the MFC 421 provided by the current sensor 431. The signal processing circuit 400 may include, for example, a high-pass filter 432 connected to an output of the current sensor 431, an operational amplifier 433 connected to an output of the high-pass filter 432, and a signal comparator 434. The high-pass filter 432 may have a 3-dB corner frequency of 10 MHz or higher letting only frequency components that are higher than 10 MHz to pass through. The signal comparator 434 has two input ports with a first input port being connected to an output of the operational amplifier 433 and a second input port being connected to a spike reference device 444. An output of the signal comparator 434 is then connected to an event counter 451. The signal processing circuit 400 may function similarly to the signal processing circuit 100 as being described above with regard to the high-voltage system 10.

In addition to signal processing circuit 400, the high-voltage system 40 may further include a capacitance measurement circuit 401 that is adapted to provide real-time measurement of current-voltage-charge relationship in the MFC 421. The capacitance measurement circuit 401 may include a first low-pass circuit, which is a first branch that taps off the current sensor 431 to receive a current signal in the MFC 421. The current signal is then passed through a low-pass filter 462, which may have a 3-dB corner frequency of 100 kHz or less to remove most of high-frequency components in the current signal that may be related to possible spikes caused by PD events in the MFC 421. The capacitance measurement circuit 401 may also include a second low-pass circuit, which is a second branch that directly taps off the two terminals of the MFC 421, thereby receiving a voltage signal that is fed into a low-pass filter 472. A first operational amplifier 463 receives a filtered current signal from the low-pass filter 462 and passes that current signal to a first input port of an integrator 481; and a second operational amplifier 473 receives a filtered voltage signal from the low-pass filter 472 and passes that voltage signal to a second input port of the integrator 481. The integrator 481 is adapted to provide an estimation about the capacitance of the MFC 421, based on the current and voltage signals from the first and second operational amplifiers 463 and 473 of the first and second low-pass circuits. Furthermore, based on the estimated capacitance of the MFC 421, embodiments of present invention enables assessment of status of health of the MFC 421, and provides facts that may be used in making proper judgement whether the MFC 421 may be needed for a replacement before causing unexpected failure of the high-voltage system where it is used.

According to one embodiment, the electric signal detected from the MFC 121, 221, 321, and/or 421, when being used in an AC main circuit with power converter, may be processed by their respective signal processing circuit 100, 200, 300, and/or 400 by applying a blanking topology to prevent an attempt to perform measurement/processing during power converter switch cycles. The blanking may help improve measurement sensitivity during the operation of the power converter. Embodiments of the blanking may include performing blanking in an analog fashion by blocking circuit operation at specific timings or digitally by simply not performing a measurement during specific times. For example, since every on/off transition of the power converter may create electrical noise that may impair capacitor test, blanking may be performed during such transition periods. Drive signal of the power converter may be used to provide timing in the blanking.

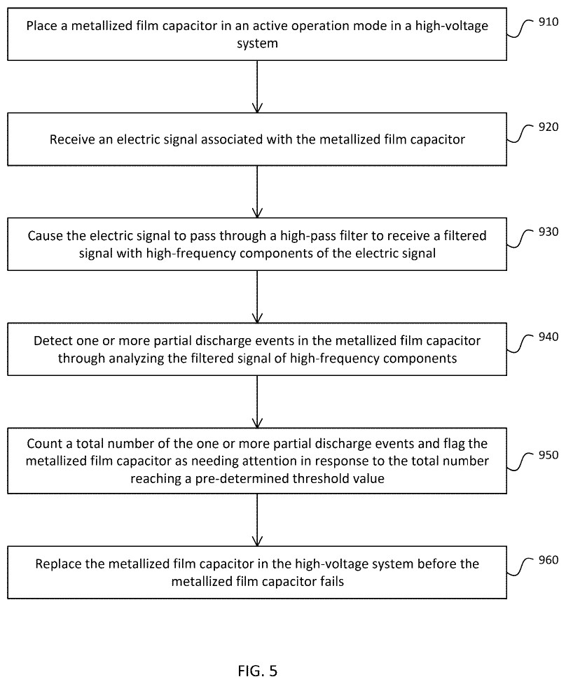

FIG. 5 is a demonstrative illustration of a flow-chart of a method of preventing a high-voltage system failure according to embodiments of present invention. The method includes (910) placing a metallized film capacitor in an active operation mode in a high-voltage system; (920) receiving an electric signal associated with the metallized film capacitor; (930) causing the electric signal to pass through a high-pass filter to receive high-frequency components of the electric signal; (940) detecting one or more partial discharge events in the metallized film capacitor through analyzing the filtered signal with high-frequency components of the electric signal; (950) counting a total number of the one or more partial discharge events and flag the metallized film capacitor as needing attention in response to the total number of partial discharge events reaching a threshold value; and (960) replacing the metallized film capacitor in the high-voltage system before the metallized film capacitor fails.

The descriptions of various embodiments of the present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A method of preventing a high-voltage system failure, the method comprising:
placing a metallized film capacitor (MFC) in an active operation mode in a high-voltage system;
detecting one or more partial discharge (PD) events in the MFC;
counting the one or more PD events; and
in response to a total number of the one or more PD events reaching a pre-determined threshold, replacing the MFC in the high-voltage system before the MFC fails.

2. The method of claim 1, further comprising:
receiving an electric signal at the MFC; and
detecting the one or more PD events by analyzing the electric signal.

3. The method of claim 2, wherein analyzing the electric signal comprises:
causing the electric signal to pass through a high-pass filter thereby receiving a filtered signal having no low-frequency components of the electric signal;
comparing the filtered signal with a spike reference; and
counting as one PD event in response to the filtered signal being equal to or larger than the spike reference.

4. The method of claim 3, wherein the high-pass filter has a 3-dB corner frequency of 10 megahertz (MHz) or higher.

5. The method of claim 2, wherein the electric signal is a fraction of an electric current passing through one terminal of the MFC, the electric current flowing between the one terminal of the MFC and a common-mode filter in the high-voltage system.

6. The method of claim 2, wherein the electric signal is a voltage signal measured at two terminals of the MFC and is received through a pair of tapping capacitors.

7. The method of claim 2, wherein the electric signal is a voltage signal measured at two opposing sides of the MFC and is received through a pair of metal plates placed at the two opposing sides of the MFC.

8. The method of claim 2, further comprising:
causing the electric signal to pass through a low-pass filter thereby receiving a current signal having no PD related components of the electric signal;
measuring a voltage across two terminals of the MFC;
estimating a capacitance of the MFC based on the current signal and the measured voltage; and
replacing the MFC in response to the capacitance of the MFC being estimated to be below a pre-determined value.

9. A high-voltage system comprising:
an AC main circuit;
a metallized film capacitor (MFC) connected to the AC main circuit via a common-mode filter; and
a test circuit electrically coupled to the MFC,
wherein the test circuit is adapted to receive an electric signal from the MFC; detect and count partial discharge (PD) events happening in the MFC; and raise an alarm in response to a total number of the PD events reaching a pre-determined threshold.

10. The high-voltage system of claim 9, wherein the test circuit includes a high-pass filter adapted to receive a filtered signal, from the electric signal, with no low-frequency components of the electric signal; a comparator to compare the filtered signal with a spike reference to detect the PD events; and an event counter to count the PD events.

11. The high-voltage system of claim 10, wherein the high-pass filter has a 3-dB corner frequency of 10 megahertz (MHz) or higher.

12. The high-voltage system of claim 9, wherein the electric signal is a fraction of an electric current and the test circuit includes a current sensor connected to one terminal of the MFC to receive the fraction of the electric current.

13. The high-voltage system of claim 9, wherein the electric signal is a voltage signal, and the test circuit includes two tapping capacitors connected respectively to two terminals of the MFC to receive the voltage signal.

14. The high-voltage system of claim 9, wherein the electric signal is a voltage signal, and the test circuit includes two metal plates placed at two opposing sides of the MFC electrically coupled to the MFC to receive the voltage signal.

15. The high-voltage system of claim 9, wherein the test circuit further includes a first low-pass circuit adapted to receive a current signal having no PD related components of the electric signal; a second low-pass circuit adapted to measure a voltage across two terminals of the MFC; and an integrator adapted to estimate a capacitance of the MFC based on the current signal and the measured voltage.

16. A method of preventing high-voltage system failure, the method comprising:
placing a metallized film capacitor (MFC) in an active operation mode in a high-voltage system;
receiving an electric signal associated with the MFC;
detecting one or more partial discharge (PD) events in the MFC by analyzing the electric signal;
counting the one or more PD events; and
in response to a total number of the one or more PD events reaching a pre-determined threshold, recommending the MFC in the high-voltage system being replaced.

17. The method of claim 16, wherein detecting the one or more PD events comprises:
causing the electric signal to pass through a high-pass filter thereby receiving a filtered signal having no low-frequency components of the electric signal;
comparing the filtered signal with a spike reference; and
counting as one PD event in response to the filtered signal carrying a same characteristic as a characteristic provided by the spike reference.

18. The method of claim 17, wherein the characteristic provided by the spike reference is selected from a group consisting of frequency components; shape of electric current, shape of voltage signal; and amplitude of electric signal.

19. The method of claim 17, wherein the high-pass filter has a 3-dB corner frequency of 10 megahertz (MHz) or higher.

20. The method of claim 17, further comprising, in response to a total number of the one or more PD events reaching the pre-determined threshold, recommending replacing the MFC by raising an alarm, making a voice announcement, or sending out a text message.
